(19) United States
(12) Patent Application Publication
(10) Pub. No.: US 2026/0097989 A1
(43) Pub. Date: Apr. 9, 2026

(54) METHOD FOR PRODUCING A MIRROR SUBSTRATE OF AN OPTICAL ELEMENT, OPTICAL ELEMENT AND PROJECTION EXPOSURE APPARATUS

(71) Applicant: Carl Zeiss SMT GmbH, Oberkochen (DE)

(72) Inventors: Andreas NITTKE, Adelschlag (DE); Klaus SCHEULEN, Heppenheim (DE)

(21) Appl. No.: 19/418,133

(22) Filed: Dec. 12, 2025

(30) Foreign Application Priority Data
Jun. 14, 2023 (DE) 10 2023 205 562.7

(51) Int. Cl. C03C 29/00; C03C 8/24; C03C 27/02; G03F 7/00

(52) U.S. Cl. CPC C03C 29/00; C03C 8/24; C03C 27/02; G03F 7/702; G03F 7/70233

(57) ABSTRACT

A method for producing a mirror substrate of an optical element for a projection exposure apparatus, in particular an EUV projection exposure apparatus, comprising a first and at least one second component, wherein the first component and the at least one second component consist of silicon at least on a side facing a connection, and the method includes the following steps: providing/producing the at least two components of the mirror substrate and joining the at least two components by heating to a joining temperature and applying a joining pressure, preferably perpendicular to a joining surface.

### CROSS-REFERENCE TO RELATED APPLICATION

This is a Continuation of International Application PCT/EP2024/065994, which has an international filing date of June 10, 2024, and the disclosure of which is incorporated in its entirety into the present Continuation by reference. This Continuation also claims foreign priority under 35 U.S.C. §119(a)-(d) to and also incorporates by reference, in their entirety, German Patent Application DE 102023 205 562.7filed on June 14, 2023.

### FIELD

Microlithography is used to produce microstructured components, for example integrated circuits. The microlithography process is performed using a lithography apparatus that comprises an illumination system and a projection system. The image of a mask (reticle) illuminated by the illumination system is projected by the projection system onto a substrate, for example a silicon wafer, which is coated with a light-sensitive layer (photoresist) and is arranged in the image plane of the projection system, in order to transfer the mask structure to the light-sensitive coating of the substrate.

### BACKGROUND

The use of EUV radiation, i.e., radiation at wavelengths of approximately 13.5 nm for example, allows very small structures to be produced on the substrate by a lithography apparatus. This can be used to further advance a reduction in structure size during the production of semiconductor components, for example.

In illumination and projection systems designed for the EUV range, mirrors are used as optical elements for the imaging process owing to the lack of availability of suitable light-transmissive materials. These optical elements for EUV systems are for example produced from crystals, such as silicon, but also from high-performance glass ceramics or metals. To this end, various methods are used to produce blocks of these materials, from which the mirror substrates for the optical elements are carved out by subtractive contouring methods. This production of the optical elements is complex and cost-intensive, especially in the case of large mirror sizes. As a result of the powers of the light sources increasing from generation to generation, it is also particularly advantageous if the mirror substrates comprise fluid channels through which temperature-controlled water flows to dissipate the heat from the optically active surface. Hence, the optical elements can be operated at an advantageous operating temperature with a minimized temperature gradient in the mirror substrate. This allows a deformation of the optically active surface to be counteracted, whereby disadvantageous effects on the imaging quality of the optical element are reduced. Drilling is one possible method of producing the fluid channels but usually has the disadvantage that the bores can only be driven straight through the mirror substrate. Regarding the production of mirror substrates from the conventional art that consist of silicon at least in part, reference is made to the documents DE 102018207759 A1 and DE 102014222952 A1.

### SUMMARY

Against this background, one problem addressed by the techniques disclosed herein is that of providing an improved method for producing a mirror substrate of an optical element for a projection exposure apparatus.

The method according to the disclosed techniques for producing a mirror substrate of an optical element for a projection exposure apparatus, in particular an EUV projection exposure apparatus, comprises a first and at least one second component, wherein the first component and the at least one second component consist of silicon at least on a side facing a connection in each case, i.e., a connection formed between the first component and the at least one second component.

In the method, the at least two components of the mirror substrate (i.e., the first component and that at least one second component) are initially produced and/or provided. Methods known from the conventional art, for example, may be used to this end. Furthermore, this step may also comprise surface processing, for example lapping or polishing a respective silicon joining surface of the at least two components, in order to improve the joining capability thereof. In the context of this disclosure, the connection means a region between the at least two components which is formed by the joining together of the two joining surfaces. In the context of this disclosure, the joining surface means the surface over which a joining process of the at least two components takes place.

In a further step of the method according to the disclosed techniques, the at least two components are joined together by heating to a joining temperature and applying a joining pressure. In this case, the joining pressure is preferably applied perpendicular to the joining surfaces such that the joining together of the two components is assisted to the greatest possible extent. In particular, the two joining surfaces are oriented parallel to each other to this end.

In an embodiment of the method, the at least two components are joined together in an evacuated environment. A vacuum provides particularly clean conditions for the process of joining the components since gaseous contaminants in the immediate surroundings, in particular, are removed. Likewise, the vacuum lowers the required joining temperatures, and so the joining process can be implemented more effectively. In this case, a vacuum of 100-10⁻⁷ mbar, preferably from 10⁻¹ to 10⁻³ mbar is set.

In a further embodiment of the method, at least one fluid channel structure is formed in the region of the connection in the resultant mirror substrate when the at least two components are joined. At least one of the two components may have prestructuring in, for example, the form of a groove for the formation of the at least one fluid channel structure. In a first variant of the embodiment, only one of the two components contains prestructuring, and so the second component acts like a type of cover during the joining process, whereby the fluid channel structure arises in the resultant mirror substrate. In a second variant of the embodiment, both components have such prestructuring, and so the fluid channel structure in the resultant mirror substrate of the optical element is composed of two parts. In this case, the prestructuring has rectangular contours and/or rounded-off rectangular contours and/or round contours and/or oval contours. In a further variant of the embodiment of the method, the surface structure of the fluid channel structures is processed by a chemical and/or a physical processing method post joining. Both variants of the embodiment dispense with complicated processing of the mirror substrate for the introduction of fluid channel structures by a subtractive method after the at least two components have been joined together. On account of the at least one fluid channel structure, a mirror substrate produced in this way allows active temperature control of the optical element during the later operation of the projection exposure apparatus or during a further processing step for the mirror substrate. Deformation-induced imaging aberrations caused by, for example, radiation-induced heat input, may thus be minimized.

In a further embodiment of the method, the first component and the at least one second component are joined directly to each other. As a result, no foreign substances are introduced in a region of the connection of the two components. Rather, direct joining of the two joining surfaces consisting of silicon allows the construction of monolithic structures in the region of the connection, and these are distinguished by particular stability.

In a further embodiment of the method, in which the first component and the at least one second component are joined directly to each other, an RMS value of the surface roughness of at least one joining surface of the at least two components is less than five nanometers. The necessary joining pressure may be reduced as a result of this low surface roughness. In this case, an RMS value of the surface roughness of a joining surface composed of silicon can be achieved with a low polishing outlay of approximately one day.

In a further embodiment of the method, in which the first component and the at least one second component are joined directly to each other, the joining temperature is 1100-1250°C. Silicon has a brittle-ductile transition in the range of 700-1100°C. In order not to risk any fracture, it is thus particularly advantageous for the joining temperature to be above 1100°C. Furthermore, the maximum joining temperature should be at approx. 90% of the melting point of silicon, which corresponds to approx. 1250°C.

In a further embodiment of the method, in which the first component and the at least one second component are joined directly to each other, the joining pressure is 0.1 MPa – 15 MPa, preferably 0.3-0.8 MPa and particularly preferably 0.5 MPa. The required joining pressure depends on the roughness and waviness of the silicon surfaces. The rougher and wavier the surfaces, the greater the required pressure. In the case of a roughness corresponding to an RMS value of 5 nm, a joining pressure of 0.5 MPa, for example, has proven to be particularly advantageous.

In a further embodiment of the method, a mediator layer is provided for joining the first component and the at least one second component. This step takes place prior to the actual joining by heating to a joining temperature and applying a joining pressure. In this case, the mediator layer is placed between the silicon joining surfaces of the at least two components for the joining process. As a result, the first component and the at least one second component are not joined directly to each other. In this context, the mediator layer enables the connection of at least two joining surfaces with an increased surface roughness. In addition, a lower joining temperature may be applied as a result of an appropriate material selection.

In a further embodiment of the method in which a mediator layer is provided for joining the first component and the at least one second component, at least one joining surface of the at least two components has a convex form. This convex curvature may be due to the preprocessing of the joining surface, in particular polishing. Typical flatness values lie in the range of 10 µm – 50 µm.

In a further embodiment of the method in which the mediator layer is provided for joining the at least two components, an RMS value of the surface roughness of at least one joining surface of the at least two components is less than 100 nanometers. This RMS value can be realized with simple cloth polishing.

In a further embodiment of the method in which the mediator layer is provided for joining the first component and the at least one second component, the mediator layer has a layer thickness of 5 µm to 1.5 mm. This range of possible layer thicknesses allows for different extents of the waviness of the joining surfaces of the at least two components to be addressed. In this case, the waviness of the joining surfaces should not exceed the layer thickness of the mediator layer, e.g., a glass film, and is preferably less than 10% of the layer thickness. At the same time, a layer thickness of 5 µm to 1.5 mm of the mediator layer ensures good handing thereof, in such a way that it can be provided as far as possible without damage.

In a further embodiment of the method in which the mediator layer is provided for joining the first component and the at least one second component, the joining temperature is above, preferably 10% above, a glass transition temperature of the mediator layer. This ensures deformability of the mediator layer, whereby as complete as possible contact of the mediator layer with the joining surfaces is achieved, even in the case of relatively large waviness of the joining surfaces. This allows the proportion of inclusions that arises in the region of the connection as a result of incomplete contact between a joining surface and the mediator layer to be minimized. In addition, the deformability may lower the required joining pressure.

In a further embodiment of the method in which the mediator layer is provided for joining the at least two components, the mediator layer consists of borosilicate glass, alkali-free glass or silicon.

In a further embodiment of the method, in which the first component and the at least one second component are joined directly to each other, the joining pressure is 0.1 MPa – 15 MPa, preferably 0.3-0.8 MPa and particularly preferably 0.5 MPa. The required joining pressure depends on the roughness and waviness of the silicon surfaces. The rougher and wavier the surfaces, the greater the required pressure. In the case of a roughness corresponding to an RMS value of 5 nm, a joining pressure of 0.5 MPa, for example, has proven to be particularly advantageous.

Further aspects of the disclosed techniques relate to an optical element having a mirror substrate produced by a method as claimed in any of claims 1 to 13.

In a further aspect, the disclosed techniques also relate to an optical element having a mirror substrate, in which there is an abrupt change in at least one chemical and/or physical property of the mirror substrate in at least one spatial direction.

Furthermore, the disclosed techniques relate to a projection exposure apparatus for semiconductor lithography, comprising at least one optical element, wherein at least one of the optical elements is at least partially produced by a method as disclosed herein, including all such embodiment of the methods, and/or at least one of the optical elements is an optical element with a structure as disclosed herein.

This results in the aforementioned advantages for the optical element according to the disclosed techniques and for the projection exposure apparatus according to the disclosed techniques. Further advantages and preferred features are evident from the description above and from the claims.

### BRIEF DESCRIPTION OF THE DRAWINGS

The techniques disclosed herein are elucidated in detail hereinafter by the drawings. In this respect:

FIG. 1 shows an EUV projection exposure apparatus,

FIGS. 2A and 2B show a device for the method according to the disclosed techniques for producing a mirror substrate by directly connecting two components,

FIGS. 3A and 3B show a device for an embodiment of the method according to the disclosed techniques for producing a mirror substrate with fluid channels,

FIGS. 4A and 4B show a device for an embodiment of the method according to the disclosed techniques for producing a mirror substrate by connecting two components via a mediator layer,

FIGS. 5A and 5B show a device for an embodiment of the method according to the disclosed techniques for producing a mirror substrate by connecting two components via a mediator layer, wherein the surfaces to be joined have a convex form, and

FIG. 6 shows a flowchart of an embodiment of the method according to the disclosed techniques.

### DETAILED DESCRIPTION

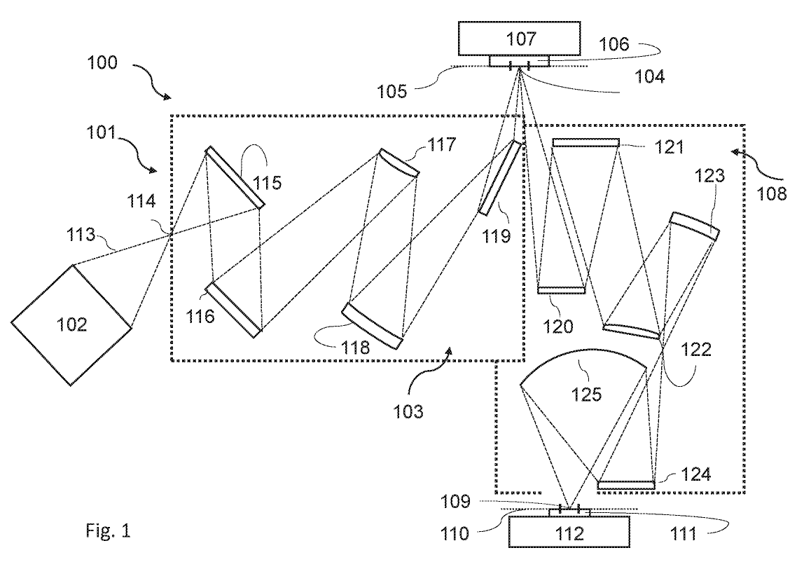

FIG. 1 shows the basic structure of an EUV projection exposure apparatus (100) for semiconductor lithography by way of example.

In addition to a radiation source (102), an illumination system (101) of the projection exposure apparatus (100) comprises an illumination optics unit (103) for illuminating an object field (104) in an object plane (105). A reticle (106) that is arranged in the object field (104) and held by a reticle holder (107) is schematically illustrated in part. A projection optics unit (108) serves for imaging the object field (104) into an image field (109) in an image plane (110). A structure on the reticle (106) is imaged onto a light-sensitive layer of a wafer (111) that is arranged in the region of the image field (109) in the image plane (110) and held by a wafer holder (112), likewise illustrated in part.

The radiation source (102) can emit EUV radiation (113), in particular in the range between 5 nm and 30 nm, such as 13.5 nm. Mechanically adjustable optical elements with different optical designs are used for controlling the radiation path of the EUV radiation (113). In the case of the EUV projection exposure apparatus (100) illustrated in FIGURE1, the optical elements are in the form of adjustable mirrors in suitable embodiments that are mentioned merely by way of example hereinafter. Individual elements in the form of mirrors may consist here of multiple segments with mutually separate optical partial surfaces.

The EUV radiation (113) generated by the radiation source (102) is aligned via a collector mirror integrated in the radiation source (102) such that the EUV radiation (113) passes through an intermediate focus in the region of an intermediate focal plane (114) before the EUV radiation (113) is incident on a field facet mirror (115). The EUV radiation (113) is reflected off a pupil facet mirror (116) downstream of the field facet mirror (115). Field facets of the field facet mirror (115) are imaged into the object field (104) with the aid of the pupil facet mirror (116) and further mirrors (117, 118, 119). In this regard, see US9411241B2 accordingly.

The reticle (106) arranged in the object field (104) may be, for example, a reflective photomask, which comprises reflective and non-reflective, or at least less reflective, regions for generating at least one structure on the reticle (106). Alternatively, the reticle (106) may be a plurality of micromirrors, which are arranged in a one-dimensional or multi-dimensional arrangement and which are optionally movable about at least one axis in order to set the angle of incidence of the EUV radiation on the respective mirror.

The reticle (106) reflects some of the beam path of the illumination optics unit (103) and shapes a beam path in the projection optics unit (108) that beams information about the structure of the reticle into the projection optics unit (108), with the information generating an image representation of the reticle or of a respective partial region thereof on the wafer (111) arranged in the image plane (110). The wafer comprises a semiconductor material, e.g., silicon, and is arranged on a wafer holder (112), which is also referred to as a wafer stage.

In the present example, the projection lens (108) comprises six reflective optical elements (120) to (125) in the form of mirrors for generating an image of the reticle (106) on the wafer (111). Typically, the number of mirrors in a projection lens (108) is between four and eight, however, it is optionally also possible to use only two mirrors or even ten mirrors. Projection lenses are known from US2016/0327868A1 and DE102018207277A1.

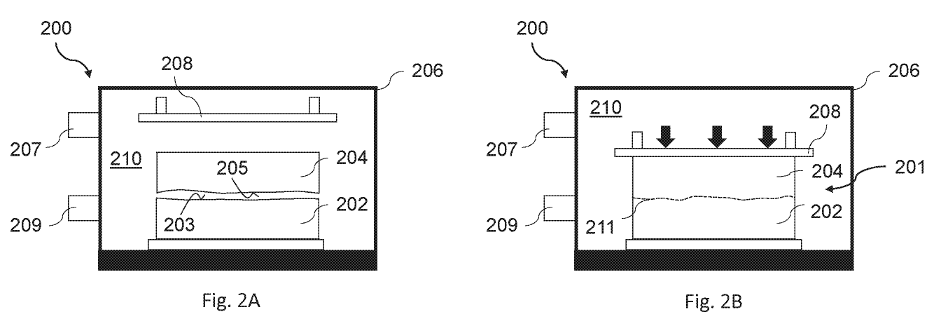

FIGS. 2A and 2B each show a device (200) for the method according to the techniques disclosed herein for producing a mirror substrate (201) of an optical element for a projection exposure apparatus, in particular an EUV projection exposure apparatus (100) according to FIG. 1.

To this end, a first component (202) having a first joining surface (203) and a second component (204) having a second joining surface (205) are provided in a chamber (206) in FIG. 2A. In this case, the components (202), (204) illustrated in FIGS. 2A and 2B consist of silicon. However, it is also possible for the components (202), (204) to consist of silicon only in a region of the joining surfaces (203), (205).

The two joining surfaces (203) and (205) are advantageously oriented parallel to each other and preferably have an RMS value for the surface roughness that is at least less than five nanometers. The chamber (206) comprises a heating device (e.g., heater) (207) configured to heat the two components (202), (204) to a joining temperature and a pressing device (208) configured to apply a joining pressure, preferably perpendicular to the joining surfaces (203), (205). The heating device (207) for heating the two components (202), (204) may be, for example, a media-based temperature control device for integral temperature control of the chamber (206). Furthermore, the heating device (207) may be, for example, embodied as a radiant heater for targeted temperature control of the two components (202), (204). A joining temperature of 1100-1250°C is typically achieved by the heating device (207) configured to heat the first component (202) and the second component (204).

In this exemplary embodiment, the pressing device (208) configured to apply a joining pressure to the components (202), (204) to be joined is embodied as a stamp placed in the upper chamber region of the chamber (206). Furthermore, the chamber (206) comprises an evacuator or pump(209) configured to evacuate an interior (210) of the chamber (206). As a result, the two components (202), (204) may optionally be joined in an evacuated environment. For example, the evacuator (209) may be embodied as a vacuum pump, by which a vacuum of 100-10⁻⁷ mbar, preferably from 10⁻¹ to 10⁻³ mbar, can be set in the interior (210). The vacuum provides particularly clean conditions for the process of joining the two components (202), (204) since gaseous contaminants in the immediate surroundings of the interior (210), in particular, are removed. Likewise, the vacuum lowers the required joining temperatures, and so the joining process can be implemented more effectively.

In FIG. 2B, a joining pressure is applied to both components (202), (204) in a manner perpendicular to the two joining surfaces by way of a targeted movement (symbolized by black arrows) of the pressing device (208) in the direction of the second component (204). The joining pressure is advantageously in the range of 0.1 MPa – 15 MPa, preferably 0.3-0.8 MPa. As a result, a connection (211) is formed between the two components (202), (204) in a region of the joining surfaces (203), (205) previously present, whereby the mirror substrate (201) is formed by the two components (202), (204). The two components (202), (204) are joined directly to each other in this exemplary embodiment. Direct joining of the two joining surfaces (203), (205) consisting of silicon sees the construction of preferably monolithic structures in the region of the connection (211), and these are distinguished by particular stability.

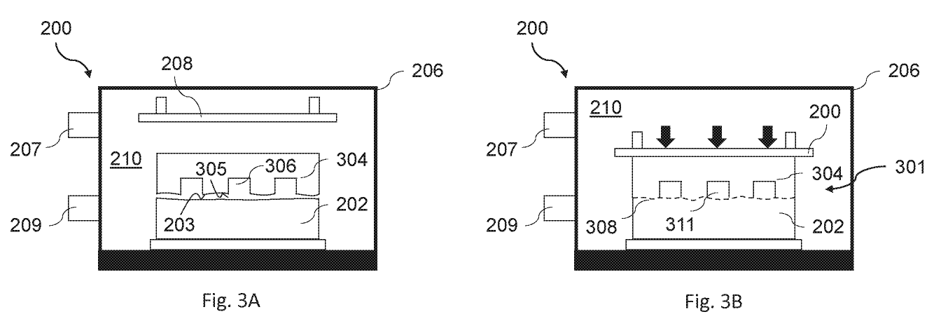

FIGS. 3A and 3B likewise show the device (200) for a further embodiment of the method according to the disclosed techniques for producing a mirror substrate (301) of an optical element for a projection exposure apparatus, in particular an EUV projection exposure apparatus (100) according to FIG. 1.

In this context, the mirror substrate (301) in FIG. 3B has multiple fluid channel structures (311) in the region of a connection 308 which arise as a result of joining the first component (202) to a second component (304). The second component (304) likewise consists of silicon but may also consist of silicon only in regions around a joining surface (305). In the variant of the embodiment shown, the second component (304) comprises prestructuring in the form of multiple grooves (306) for the formation of the fluid channel structures, and so the first component (202) acts as a type of cover during the joining operation, whereby the fluid channel structures (311) arise in the resulting mirror substrate (301) of the optical element. In a further variant of the embodiment, the component (202) additionally also has such prestructuring. In this case, the prestructuring of the component and/or the components has rectangular contours and/or round contours and/or oval contours. In a further variant of the embodiment of the method, the surface structure of the fluid channel structures is processed by a chemical and/or a physical processing method post joining. Both variants of the embodiment dispense with complicated processing of the mirror substrate for the introduction of fluid channel structures via a subtractive method after the at least two components have been joined together. On account of the fluid channel structures (311), a mirror substrate (301) produced in this way allows active temperature control of the optical element during later operation of the projection exposure apparatus. Deformation-induced imaging aberrations caused by, for example, radiation-induced heat input, may thus be minimized.

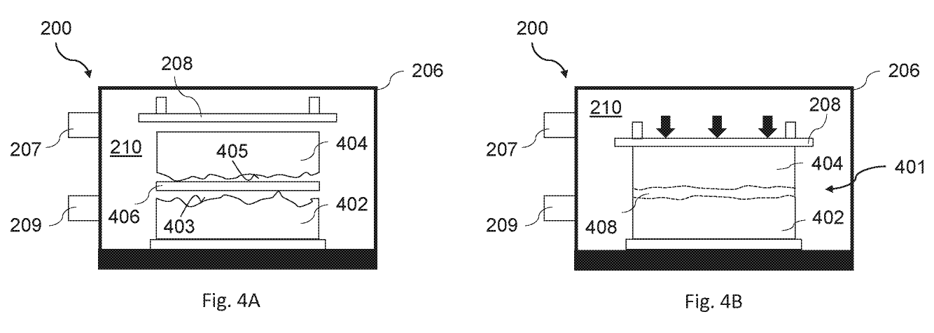

FIGS. 4A and 4B likewise show the device (200) for a further embodiment of the method according to the disclosed techniques for producing a mirror substrate (401) of an optical element for a projection exposure apparatus, in particular an EUV projection exposure apparatus (100) according to FIG. 1.

To this end, a first component (402) having a first joining surface (403) and a second component (404) having a second joining surface (405) are provided in the chamber (206) in FIG. 4A. In this case, the components (402), (404) illustrated in FIGS. 4A and 4B consist of silicon. However, it is also possible for the components (402), (404) to consist of silicon only in a region of the joining surfaces (403), (405). This embodiment is characterized by a mediator layer (406), which is provided for joining the first component (402) and the second component (404). In this case, the mediator layer (406) typically has a thickness of 5 µm to 1.5 mm and typically consists of borosilicate glass, alkali-free glass or silicon. The two joining surfaces (403) and (405) are advantageously oriented parallel to each other and preferably have an RMS value for the surface roughness that is less than 100 nanometers. This RMS value can be obtained with simple cloth polishing. Thus, the provision of the mediator layer (406) generally improves the ability to join components tending to have increased roughness.

For the joining process, the heating device (207) provides a joining temperature that is above, preferably 10% above, a glass transition temperature of the mediator layer (406). This ensures deformability of the mediator layer (406), whereby as complete as possible contact of the mediator layer with the joining surfaces (403), (405) is achieved, even in the case of relatively large waviness of the joining surfaces (403), (405). This allows the proportion of inclusions that arises in the region of the connection (408) as a result of incomplete contact between at least one joining surface (403), (405) and the mediator layer (406) to be minimized. In addition, the deformability may lower the required joining pressure.

As shown in FIG. 4B, the joining pressure is applied to both components (402), (404) and to the mediator layer (406) connecting the components, in a manner perpendicular to the two joining surfaces (403), (405) by way of a targeted movement (symbolized by black arrows) of the pressing device (208) in the direction of the second component (404). The joining pressure is advantageously in the range of 0.1 MPa – 15 MPa, preferably 0.3-0.8 MPa. As a result, a connection (408) is formed between the two components (402), (404) in a region of the joining surfaces (403), (405) previously present that should be connected by the mediator layer (406), whereby the mirror substrate (401) is formed by the two components (402), (404). Furthermore, the chamber (206) comprises the evacuator (209) configured to evacuate the interior (210) of the chamber (206) in this exemplary embodiment, too. As a result, the two components (402), (404) and the mediator layer may optionally be joined in an evacuated environment.

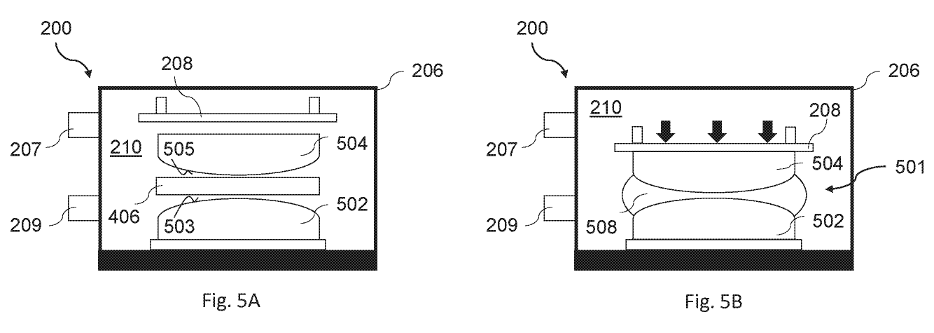

FIGS. 5A and 5B likewise show the device (200) for a further embodiment of the method according to the disclosed techniques for producing a mirror substrate (501) of an optical element for a projection exposure apparatus, in particular an EUV projection exposure apparatus (100) according to FIG. 1.

To this end, a first component (502) having a first joining surface (503), a second component (504) having a second joining surface (505), and the mediator layer (406) are provided in the chamber (206) in FIG. 5A. In this case, the two joining surfaces (503) and (505) have a convex form. This convex form may be due to the preprocessing of the joining surfaces (503), (505), in particular polishing. Typical flatness values lie in the range of 10 µm – 50 µm. In principle, it is also possible for only one of the two joining surfaces (503), (505) to have a convex configuration.

According to FIG. 5B, a connection (508) is formed between the two components (502), (504) in a region of the convex joining surfaces (503), (505) previously present that should be connected by the mediator layer (406), whereby the mirror substrate (501) is formed by the two components (502), (504). Here, the mediator layer (406) that has been heated to above its glass transition temperature by the heating device (207) adapts to the convex surface form of the joining surfaces (503), (505).

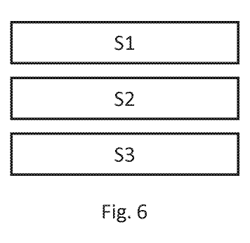

FIG. 6 shows a flowchart of an embodiment of the method according to the disclosed techniques for producing a mirror substrate of an optical element for a projection exposure apparatus, in particular an EUV projection exposure apparatus according to FIG. 1. The method in FIG. 6 can be applied to the substrates of the optical elements (215-219) and (220-225) within a projection exposure apparatus, which are shown in FIG. 1.

In a first step (S1), a first component and at least one second component are provided for producing a mirror substrate. In this case, the first component and the at least one second component consist of silicon at least on a side facing a connection. Hence, the first component and/or the at least one second component may consist entirely of silicon. It is also possible for the first component and/or the at least one second component to consist of silicon only in the region of their respective joining surfaces.

By preference, a mediator layer is provided in a second step (S2) for joining the first component and the at least one second component The use of a mediator layer is helpful especially for components with an increased surface roughness of the joining surface.

In a third step (S3), the first component and the at least one second component are joined together by heating to a joining temperature and applying a joining pressure, preferably in a manner perpendicular to the joining surfaces.

### LIST OF REFERENCE SIGNS

100 Projection exposure apparatus

101 Illumination system

102 Radiation source

103 Illumination optics unit

104 Object field

105 Object plane

106 Reticle

107 Reticle holder

108 Projection optics unit

109 Image field

110 Image plane

111 Wafer

112 Wafer holder

113 EUV radiation

114 Intermediate focal plane

115 Field facet mirror

116 Pupil facet mirror

117 – 119 Further mirrors of the illumination optics unit

120 – 125 Further optical elements of the projection optics unit

200 Device for the method according to the disclosed techniques

201 Mirror substrate according to an embodiment of the method according to the disclosed techniques

202 First component

203 First joining surface

204 Second component

205 Second joining surface

206 Chamber

207 Heating device or heater for heating

208 Pressing device or presser for applying a joining pressure

209 Evacuator or pump for evacuating

210 Chamber Interior

211 Connection

301 Mirror substrate according to an embodiment of the method according to the invention

304 Second component

306 Groove

308 Connection

311 Fluid channel

401 Mirror substrate according to an embodiment of the method according to the invention

402 First component

403 First joining surface

404 Second component

405 Second joining surface

406 Mediator layer

408 Connection

501 Mirror substrate according to an embodiment of the method according to the invention

502 First component

503 First joining surface

504 Second component

505 Second joining surface

508 Connection

S1 First method step

S2 Second method step

S3 Third method step

What is claimed is:

1. A method for producing a mirror substrate of an optical element for a projection exposure apparatus comprising:
providing a first component and at least one second component, wherein the first component and the at least one second component consist of silicon at least on a side facing a connection;
joining the first component and the at least one second component by heating the first component and the at least one second component to a joining temperature and applying a joining pressure to the first component and the at least one second component.

2. The method of claim 1, wherein the optical element comprises an optical element of an EUV exposure apparatus.

3. The method of claim 1, wherein applying the joining pressure comprises applying pressure perpendicularly to a joining surface of the first component or the at least one second component.

4. The method of claim 1, wherein the first component and the at least one second component are joined in an evacuated environment.

5. The method of claim 1, wherein at least one fluid channel structure is formed in a region of the connection when the first component and the at least one second component are joined.

6. The method of claim 1, wherein the first component and the at least one second component are joined directly to each other.

7. The method of claim 6, wherein an RMS value of a surface roughness of at least one joining surface of the first component or the at least one second component is less than five nanometers.

8. The method of claim 1, wherein the joining temperature is 1100-1250.°C.

9. The method of claim 1, wherein a mediator layer is provided for joining the first component and the at least one second component.

10. The method of claim 9, wherein at least one joining surface of the first component or the at least one second component has a convex form.

11. The method of claim 9, wherein an RMS value of a surface roughness of at least one joining surface of the first component or the at least one second component is less than 100 nanometers.

12. The method of claim 9, wherein the mediator layer has a layer thickness of 5 µm to 1.5 mm.

13. The method of claim 9, wherein the joining temperature is above a glass transition temperature of the mediator layer.

14. The method of claim 13, wherein the joining temperature is 10% above the glass transition temperature of the mediator layer.

15. The method of claim 9, wherein the mediator layer consists of borosilicate glass, silicon or alkali-free glass.

16. The method of claim 1, wherein the joining pressure is 0.1 MPa – 15 MPa.

17. The method of claim 1, wherein the joining pressure is 0.0-3..8 MPa.

18. An optical element having a mirror substrate produced by the method as claimed in claim 1.

19. The optical element of claim 18, wherein there is an abrupt change in at least one chemical and/or physical property of the mirror substrate in at least one spatial direction.

20. A projection exposure apparatus for semiconductor lithography, comprising at least one optical element as claimed in claim 18.
